(19) United States
(12) Patent Application Publication
(10) Pub. No.: US 2010/0023839 A1
(43) Pub. Date: Jan. 28, 2010

(54) Memory system and memory error cause specifying method

(75) Inventor: Masakatsu Uneme, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/458,775

(22) Filed: Jul. 22, 2009

(30) Foreign Application Priority Data
Jul. 23, 2008 (JP) 189440/2008

(51) Int. Cl. H03M 13/05; G06F 11/10

(52) U.S. Cl. 714/763; 714/E11.032; 714/819; 713/600

(57) ABSTRACT

Provided is a memory system that can specify a cause of an error. According to the memory system, during writing, when write data is looped back, and the write data is an error, the error has occurred between first processing units (51 to 53) or second processing units (56 to 58) and an input/output unit (60). Thus, whether the error has occurred between the first processing units (51 to 53) or the second processing units (56 to 58) and the input/output unit (60), or in a memory (8) can be specified.

### BACKGROUND OF THE INVENTION

1. Field of the Invention

The present invention relates to a memory system, which is capable of accessing a memory, and specifies a cause of an error occurring when accessing the memory, and a method of specifying the cause of the error.

2. Description of the Related Art

A memory system that includes an interface (I/F) for accessing a memory has been developed. As such memory systems, a microcomputer, a system on a chip (SOC), and a field programmable gate array (FPGA) are available. The memory system operates in synchronization with a clock signal. The memory is designed so that the I/F of the memory system operates in synchronization with the clock signal. As such a memory, a synchronous dynamic random access memory (SDRAM) is available.

A recent progress in subtilization of a semiconductor and speeding-up of the memory access has been accompanied by an increase in memory errors of low reproducibility. The memory error of low reproducibility may be, for example, an error due to a noise such as crosstalk, or a soft error in which data stored in a memory cell is inverted. When a memory error occurs, which component or wiring line of a mounted system is a cause thereof has to be specified.

Japanese Patent Application Laid-open No. 2002-132590 (Patent Document 1) describes a memory error isolation method. In this publication, when a memory error is detected, a cause of the error is isolated without using any measurement device such as an oscilloscope. In the memory error isolation method, a control circuit and an input/output (I/O) unit are provided. The control circuit includes a designated address holding circuit, a write data holding circuit, an error address holding circuit, and an error data holding circuit. The control circuit writes write data in a memory via the I/O unit according to a write request. In this case, when an address is a designated address, the control circuit holds the address in the designated address holding circuit, and the write data in the write data holding circuit. Read data is read from the memory according to a read request. The I/O unit outputs the read data read from the memory to the control circuit. In this case, the control circuit holds the address in the error address holding circuit, and the read data output from the I/O unit in the error data holding circuit. The control circuit checks whether or not the read data held in the error data holding circuit is an error. If a result of the check indicates that the read data is an error, the control circuit compares the address held in the error address holding circuit with the address held in the designated address holding circuit. If a result of the comparison indicates that those addresses match each other, the control circuit compares the write data held in the write data holding circuit with the read data held in the error data holding circuit. The control circuit outputs a result of the comparison.

Japanese Patent Application Laid-open NO. Sho 61-95465 (Patent Document 2) describes a memory system. In this publication, when a memory error is detected, isolation of a replacement part card of an error spot is enabled to a certain extent without any development of new software for diagnosis control. The memory system includes a control circuit and an I/O unit. The control circuit includes a write data register, a read data register, and a diagnosis result register. The control circuit writes write data in a memory via the I/O unit according to a write request. In this case, the control circuit holds the write data in the write data register. Read data is read from the memory according to a read request. The I/O unit outputs the read data read from the memory to the control circuit. In this case, the control circuit holds the read data output from the I/O unit in the read data register. The control circuit checks an error correcting code (ECC) for the read data held in the read data register. If a result of the check indicates that the read data is an error, the control circuit checks an ECC for the write data held in the write data register, and stores a result of the check in the diagnosis result register.

As described above, when a memory error occurs, which component or wiring line of the mounted system is a cause thereof has to be specified. However, when memory errors of low reproducibility occur, specifying thereof is difficult.

According to the technology described in Patent Document 1, only when the address is held in the designated address holding circuit, the control circuit compares the write data held in the write data holding circuit with the read data held in the error data holding circuit. As a result, unless an address is designated, whether or not an error has occurred cannot be checked.

According to the technology described in Patent Document 1, errors that occur in the way from the write data holding circuit to the error data holding circuit via the memory are checked. In other words, errors that occur between the control circuit and the memory are checked. However, whether an error is present between the control circuit and the memory or between the control circuit and the I/O unit cannot be specified.

According to the technology described in Patent Document 2, no address is designated unlike the technology described in Patent Document 1. Thus, only a series of operations of writing the write data in the memory according to a certain address and reading the read data from the memory according to the address can be applied. For example, when the write data is written in the memory according to a certain address, and the read data is read from the memory according to another address, whether or not an error has occurred cannot be checked.

According to the technology described in Patent Document 2, errors that occur in the way from the write data register to the read data register via the memory are checked. In other words, errors that occur between the control circuit and the memory are checked. However, whether an error is present between the control circuit and the memory or between the control circuit and the I/O unit cannot be specified.

### SUMMARY

The present invention seeks to solve one or more of the above problems, or to improve upon those problems at least in part.

Hereinafter, reference numerals used in best modes and embodiments for carrying out the present invention are bracketed, and means for solving the problems is provided. The reference numerals are only added to clarify correspondence between appended claims and the best modes and the embodiments for carrying out the present invention, but should not be used for interpretation of a technical scope of the present invention described in the claims.

In one embodiment, a memory system (5) according to the present invention includes first processing units (51 to 53), an input/output unit (60), and second processing units (56 to 58). During writing, the first processing units (51 to 53) receive write data to generate a first error correcting code (ECC) for the write data, and output the write data and the first ECC. The input/output unit (60) outputs the write data and the first ECC output from the first processing units (51 to 53) to a memory (8), and outputs the write data and the first ECC respectively as output data and a second ECC. The second processing units (56 to 58) receive the output data and the second ECC to generate a third ECC for the output data, compare the third ECC with the second ECC, and output a result of the comparison and the output data.

According to the memory system of the present invention, during the writing, when the write data is looped back, and the write data is an error, the error has occurred between the first processing units (51 to 53) or the second processing units (56 to 58) and the input/output unit (60). As a result, whether the error has occurred between the first processing units (51 to 53) or the second processing units (56 to 58) and the input/output unit (6), or in the memory (8), can be specified.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 illustrates a configuration of a memory system according to each of first and second embodiments of the present invention;

FIG. 2 illustrates a configuration of a memory controller 5 of the memory system according to the first embodiment of the present invention;

FIG. 3 illustrates an ECC generation unit 52, a first holding unit 53, an ECC checking unit 57, a second holding unit 58, and an input/output unit 60 in the memory controller 5 of the memory system according to the first embodiment of the present invention;

FIG. 4 is a timing chart illustrating an operation of the memory controller 5 of the memory system according to each of the first and second embodiments of the present invention;

FIG. 5 illustrates a configuration of the memory controller 5 of the memory system according to the second embodiment of the present invention;

FIG. 6 illustrates an ECC generation unit 52, a first holding unit 53, a first DLL (WDLL) unit 54, an ECC checking unit 57, a second holding unit 58, a second DLL (WDLL) unit 59, and an input/output unit 60 in the memory controller 5 of the memory system according to the second embodiment of the present invention; and

FIG. 7 illustrates a configuration of the second DLL unit 59 in the memory controller 5 of the memory system according to the second embodiment of the present invention.

### DETAILED DESCRIPTION OF THE PREFERRED EMBODIMENTS

Referring to the accompanying drawings, memory systems of the preferred embodiments of the present invention are described in detail.

### First Embodiment

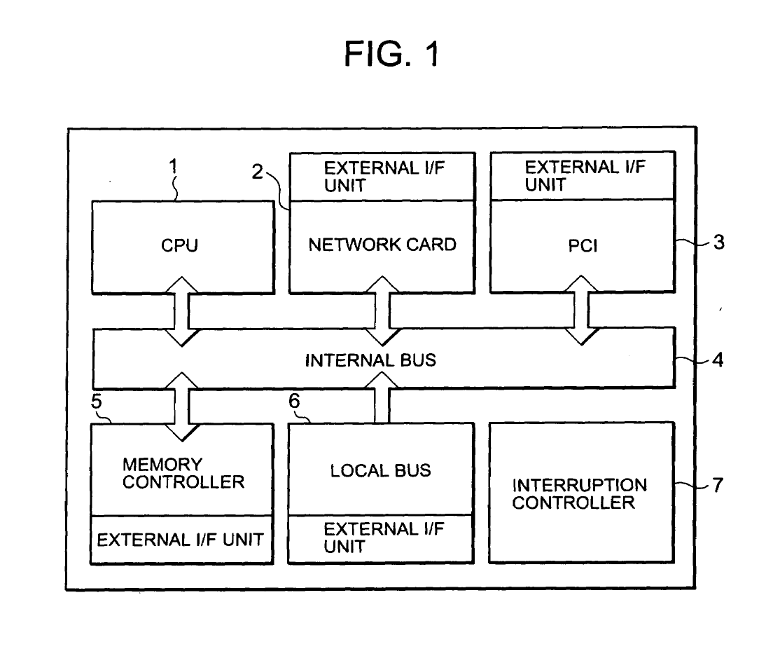

FIG. 1 illustrates a configuration of a memory system according to a first embodiment of the present invention. The memory system includes a central processing unit (CPU) 1, a network card 2, a peripheral component interconnect (PCI) 3, an internal bus 4, a memory controller 5, a local bus 6, and an interruption controller 7. The memory controller 5 is connected to the CPU 1, the network card 2, the PCI 3, the memory controller 5, and the local bus 6 via the internal bus 4. The interruption controller 7 is connected to the CPU 1, the network card 2, the PCI 3, the memory controller 5, and the local bus 6. The network card 2, the PCI 3, the memory controller 5, and the local bus 6 are connected to an external interface (I/F) unit. The memory controller 5 is connected to the memory via the I/F unit.

A writing destination such as the CPU 1, the network card 2 or the PCI 3 issues a writing request in a memory to the memory controller 5 via the internal bus 4. In this case, the memory controller 5 writes write data in the memory according to the writing request. A reading destination such as the CPU 1, the network card 2, or the PCI 3 issues a reading request in the memory to the memory controller 5 via the internal bus 4. In this case, the memory controller 5 reads read data from the memory according to the reading request.

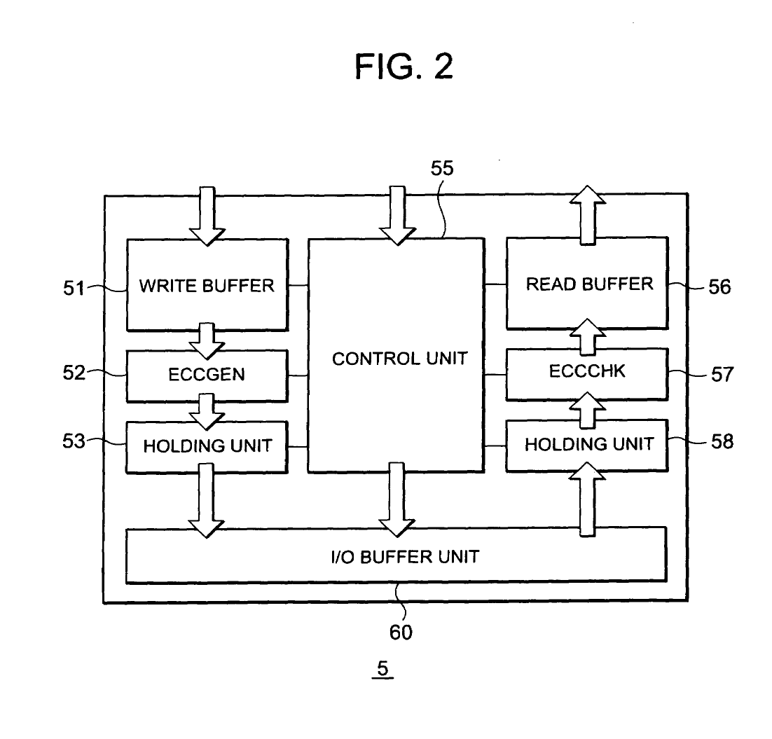

FIG. 2 illustrates a configuration of the memory controller 5. The memory controller 5 includes first processing units 51 to 53, second processing units 56 to 58, a control unit 55, and an input/output unit (I/O buffer unit) 60. The control unit 55 controls the first processing units 51 to 53 and the second processing units 56 to 58. The first processing units 51 to 53 include a write buffer unit 51, an ECC generation unit 52, and a first holding unit 53. The second processing units 56 to 58 include a read buffer 56, an ECC checking unit 57, and a second holding unit 58.

The control unit 55 receives a writing request from a writing destination and outputs the writing request to the memory.

During writing, the write buffer unit 51 receives write data and outputs the write data to the ECC generation unit 52. The ECC generation unit 52 generates first ECC for the write data, and outputs the write data and the first ECC to the first holding unit 53. The first holding unit 53 holds the write data and the first ECC from the ECC generation unit 52, and outputs the write data and the first ECC to the input/output unit 60 in synchronization with a clock signal.

The input/output unit 60 outputs the write data and the first ECC received from the first holding unit 53 to the memory. In this case, the write data and the first ECC are written in the memory according to a writing request. Simultaneously, the input/output unit 60 outputs the write data and the first ECC respectively as output data and second ECC to the second holding unit 58.

The second holding unit 58 holds the output data and the second ECC from the input/output unit 60, and outputs the output data and the second ECC to the ECC checking unit 57 in synchronization with a clock signal. The ECC checking unit 57 receives the output data and the second ECC from the second holding unit 58 to generate third ECC for the output data. Then, the ECC checking unit 57 compares the third ECC with the second ECC. If a result of the comparison indicates non-matching between the second ECC and the third ECC, the ECC checking unit 57 outputs error information indicating non-matching between the second ECC and the third ECC and the output data to an output unit. For example, the output unit is presumed to be an interruption controller 7. The interruption controller 7 executes predetermined processing according to the error information.

According to the memory system of the first embodiment of the present invention, during writing, if write data is looped back, and the write data is an error, the error has occurred between the first and second processing units 51 to 53 and 56 to 58 and the input/output unit 60. Thus, as a first effect, whether an error has occurred between the first and second processing units 51 to 53 and 56 to 58 and the input/output unit 60 or in the memory 8 can be specified.

The control unit 55 receives a reading request from a reading destination and outputs the reading request to the memory. According to the reading request, read data and corresponding ECC are read from the memory. During reading, for example, a reading control signal is presumed to be supplied from the reading destination to the ECC checking unit 57.

During the reading, the input/output unit 60 outputs the read data and the corresponding ECC received from the memory as output data and second ECC to the second holding unit 58.

The second holding unit 58 holds the output data and the second ECC from the input/output unit 60, and outputs the output data and the second ECC to the ECC checking unit 57 in synchronization with a clock signal. The ECC checking unit 57 receives the output data and the second ECC from the second holding unit 58 to generate third ECC for the output data. Then, the ECC checking unit 57 compares the third ECC with the second ECC. If a result of the comparison indicates non-matching between the second ECC and the third ECC, the ECC checking unit 57 outputs error information indicating non-matching between the second ECC and the third ECC and the output data to the output unit (interruption controller 7). The interruption controller 7 executes predetermined processing according to the error information. The ECC checking unit 57 outputs the output data as read data to the read buffer 56 according to a reading control signal. The read buffer 56 outputs the read data to the reading destination. If a reading control signal has been generated, in other words, during reading, irrespective of presence of an error, the read data is output to the reading destination via the read buffer 56.

In the case of general ECC: single error correction, double error detection (SECDED), the ECC checking unit 57 corrects a 1-bit error for the read data and outputs the corrected data.

According to the memory system of the first embodiment of the present invention, during reading, if the read data is an error, the error has occurred among the first and second processing units 51 to 53 and 56 to 58 and the input/output unit 60 and the memory 8. For example, if the write data is not an error, the error may have occurred in the memory 8. Thus, as a second effect, whether an error has occurred between the first and second processing units 51 to 53 and 56 to 58 and the input/output unit 60 or in the memory 8 can be specified.

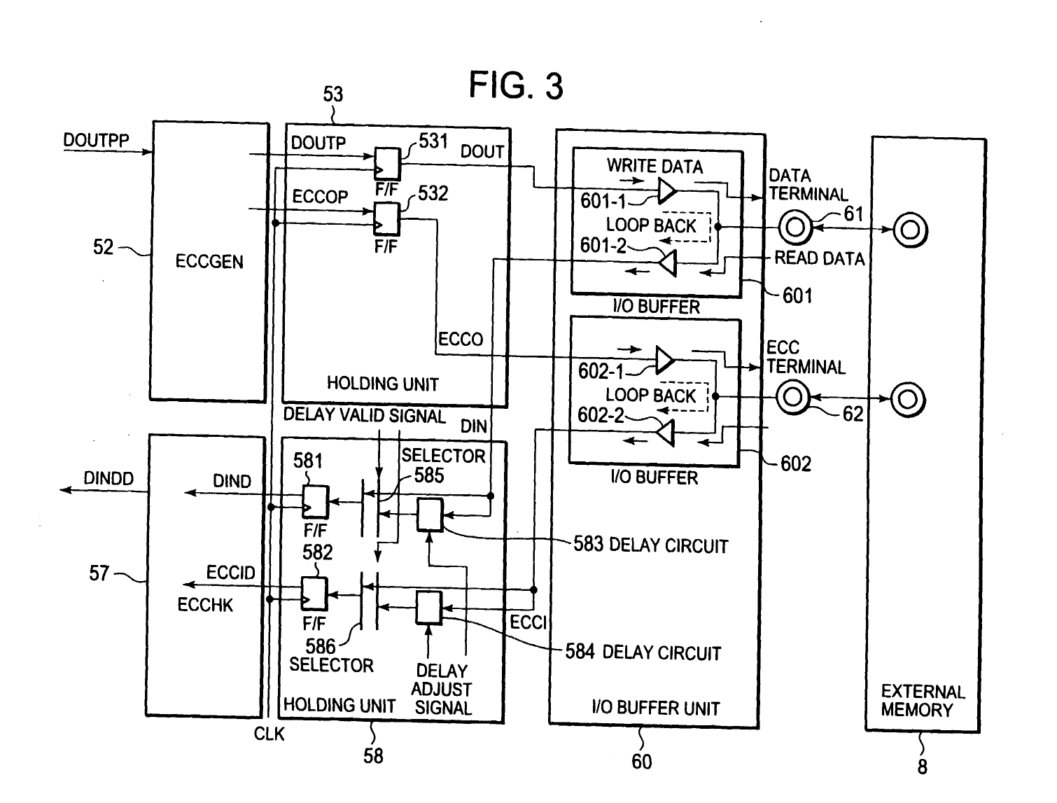

FIG. 3 illustrates the ECC generation unit 52, the first holding unit 53, the ECC checking unit 57, the second holding unit 58, and the input/output unit 60.

The memory controller 5 further includes a data terminal 61 and an ECC terminal 62. The memory 8 includes a data terminal and an ECC terminal respectively connected to the data terminal 61 and the ECC terminal 62. For example, 64 data terminals 61 and 8 ECC terminals 62 are installed, and components of the memory controller 5 are configured according to the numbers of the data terminal 61 and the ECC terminal 62.

The input/output unit 60 includes a data output unit 601. The data output unit 601 includes a first data output unit (output buffer) 601-1 and a second data output unit (output buffer) 601-2. The first data output unit 601-1 is disposed between an output of the first holding unit 53 and the data terminal 61. The second data output unit 601-2 is disposed between an output of the first data output unit 601-1 and an input of the second holding unit 58.

The input/output unit 60 further includes a data output unit 602. The data output unit 602 includes a first ECC output unit (output buffer) 602-1 and a second ECC output unit (output buffer) 602-2. The first ECC output unit 602-1 is disposed between an output of the first holding unit 53 and the data terminal 62. The second ECC output unit 602-2 is disposed between an output of the first ECC output unit 602-1 and an input of the second holding unit 58.

The first holding unit 53 includes a first data holding unit (flip-flop) 531 and a first ECC holding unit (flip-flop) 532. The first data holding unit 531 is disposed between the ECC generation unit 52 and the first data output unit 601-1. The first ECC holding unit 532 is disposed between the ECC generation unit 52 and the first ECC output unit 602-1. A clock signal CLK is supplied as a first clock signal to the first data holding unit 531 and the first ECC holding, unit 532.

The second holding unit 58 includes a second data holding unit (flip-flop) 581 and a second ECC holding unit (flip-flop) 582. The second data holding unit 581 is disposed between the ECC checking unit 57 and the second data output unit 601-2. The second ECC holding unit 582 is disposed between the ECC checking unit 57 and the second ECC output unit 602-2. The same clock signal CLK as a first clock signal is supplied as a second clock signal to the second data holding unit 581 and the second ECC holding unit 582.

The configuration of the memory system of the first embodiment of the present invention provides the first and second effects.

The second holding unit 58 further includes adjusting units 583 to 586. The adjusting units 583 to 586 are a first delay unit (delay circuit) 583, a second delay unit (delay circuit) 584, a first selection unit (selector) 585, and a second selection unit (selector) 586. The first selection unit 585 is disposed between the second data output unit 601-2 and the second data holding unit 581. The first delay unit 583 is disposed between the second data output unit 601-2 and the first selection unit 585. The second selection unit 586 is disposed between the second ECC output unit 602-2 and the second ECC holding unit 582. The second delay unit 584 is disposed between the second ECC output unit 602-2 and the second selection unit 586.

When delays caused by wiring lines from the first data holding unit 531 and the first ECC holding unit 532 to the memory 8 are not taken into consideration, a delay invalid signal is supplied to the first selection unit 585 and the second selection unit 586. When delays caused by the wiring lines are taken into consideration, a delay valid signal is supplied to the first selection unit 585 and the second selection unit 586. Though not illustrated, the delay invalid signal is presumed to be obtained by inverting a signal level of the delay valid signal. A delay adjust signal is supplied to the first delay unit 583 and the second delay unit 584. The delay adjust signal is described below.

The first selection unit 585 selects an output of the second data output unit 601-2 among outputs of the second data output unit 601-2 and the first delay unit 583 according to the delay invalid signal. The first selection unit 585 selects the output of the first delay unit 583 among outputs of the second data output unit 601-2 and the first delay unit 583 according to the delay valid signal. An operation of the first delay unit 583 is described below.

The second selection unit 586 selects an output of the second ECC output unit 602-2 among outputs of the second ECC output unit 602-2 and the second delay unit 584 according to the delay invalid signal. The second selection unit 586 selects the output of the second delay unit 584 among the outputs of the second ECC output unit 602-2 and the second delay unit 584 according to the delay valid signal. An operation of the second delay unit 584 is described below.

The configuration of the memory system of the first embodiment of the present invention provides a third effect of specifying the error by taking delays caused by wiring lines into consideration.

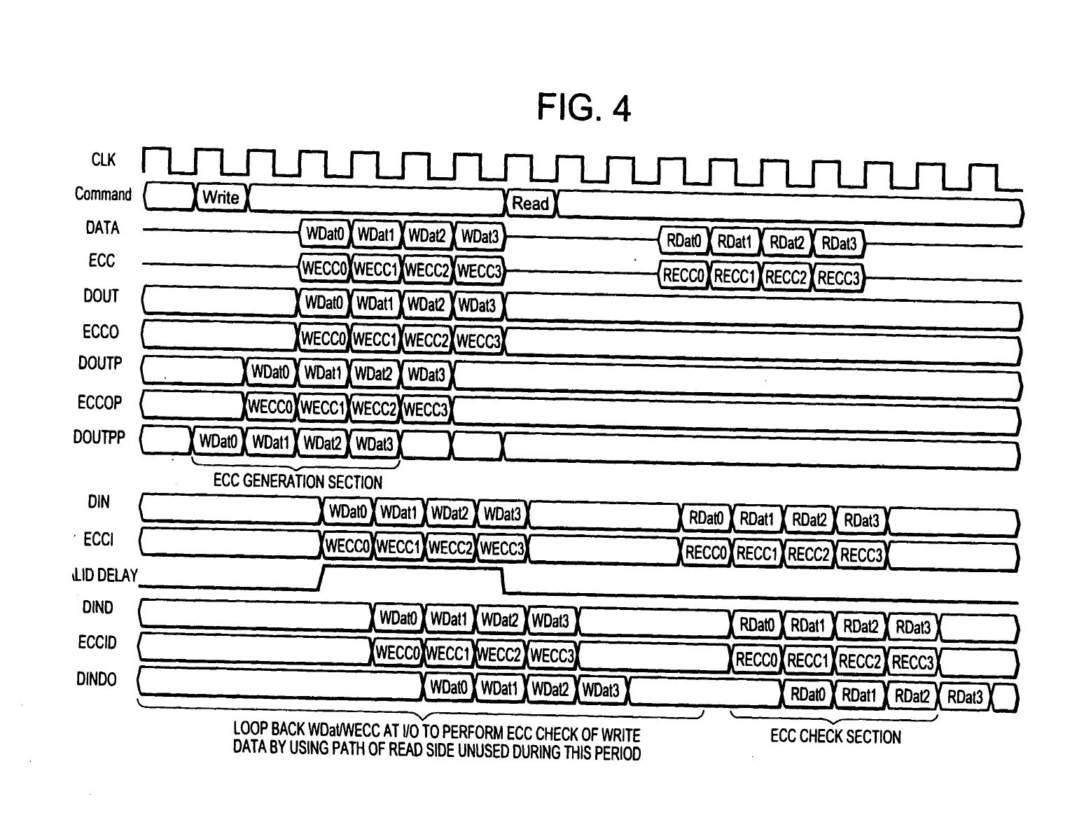

FIG. 4 is a timing chart illustrating an operation of the memory controller 5.

A case where delays caused by wiring lines are not taken into consideration is described.

First, a process during writing is described.

The ECC generation unit 52 receives write data as write data (DOUTPP) from the write buffer unit 51. The ECC generation unit 52 generates ECC as ECC (ECCOP) for the write data (DOUTPP) The ECC (ECCOP) corresponds to first ECC. The ECC generation unit 52 outputs the write data (DOUTP) and the ECC (ECCOP) respectively to the first data holding unit 531 and the first ECC holding unit 532.

The first data holding unit 531 receives the write data (DOUTP) from the ECC generation unit 52, holds the write data (DOUTP), and outputs the write data (DOUTP) as write data (DOUT) to the first data output unit 601-1 in synchronization with a clock signal CLK. The first ECC holding unit 532 receives the ECC (ECCOP) from the ECC generation unit 52, holds the ECC (ECCOP), and outputs the ECC (ECCOP) as ECC (ECCO) to the first ECC output unit 602-1 in synchronization with the clock signal CLK.

The first data output unit 601-1 outputs the write data (DOUT) from the first data holding unit 531 to the memory 8 via the data terminal 61. The second data output unit 601-2 outputs the write data (DOUT) from the first data output unit 601-1 as data (DIN). The data (DIN) corresponds to output data.

The first ECC output unit 602-1 outputs the ECC (ECCO) from the first ECC holding unit 532 to the memory 8 via the ECC terminal 62. The second ECC output unit 602-2 outputs the ECC (ECCO) from the first ECC output unit 602-1 as ECC (ECCI). The ECC (ECCI) corresponds to second ECC.

The first selection unit 585 selects an output of the second data output unit 601-2 among outputs of the second output unit 601-2 and the first delay unit 583 according to the delay invalid signal. In this case, the first selection unit 585 outputs data (DIN) from the second data output unit 601-2 to the second data holding unit 581.

The second selection unit 586 selects an output of the second ECC output unit 602-2 among outputs of the second ECC output unit 602-2 and the second delay unit 584 according to the delay invalid signal. In this case, the second selection unit 586 outputs ECC (ECCI) from the second ECC output unit 602-2 to the second ECC holding unit 582.

The second data holding unit 581 receives the data (DIN) from the first selection unit 585, holds the data (DIN), and outputs the data (DIN) as data (DIND) to the ECC checking unit 57 in synchronization with the clock signal CLK. The second ECC holding unit 582 receives the ECC (ECCI) from the second selection unit 586, holds the ECC (ECCI), and outputs the ECC (ECCI) as ECC (ECCID) to the ECC checking unit 57 in synchronization with the clock signal CLK.

The ECC checking unit 57 receives the data (DIND) from the second data holding unit 581 and the ECC (ECCID) from the second ECC holding unit 582, and generates ECC for the data (DIND). The ECC for the data (DIND) corresponds to third ECC. Then, the ECC checking unit 57 compares the ECC (ECCID) with the ECC for the data (DIND). If a result of the comparison indicates non-matching between the ECC (ECCID) and the ECC for the data (DIND), the ECC checking unit 57 outputs error information indicating non-matching between the ECC (ECCID) and the ECC for the data (DIND), and the data (DIND) to the interruption controller 7.

Next, a process during reading is described. Operations similar to those during the writing are omitted.

The second data output unit 601-2 outputs the read data from the memory 8 as data (DIN). The data (DIN) corresponds to output data.

The second ECC output unit 602-2 outputs the ECC from the memory 8 as ECC (ECCI). The ECC (ECCI) corresponds to second ECC.

The first selection unit 585 outputs the data (DIN) received from the second data output unit 601-2 to the second data holding unit 581 according to a data delay invalid signal.

The second selection unit 586 outputs the ECC (ECCI) received from the second ECC output unit 602-2 to the second ECC holding unit 582 according to a data delay invalid signal.

The second data holding unit 581 receives the data (DIN) from the first selection unit 585, holds the data (DIN), and outputs the data (DIN) as data (DIND) to the ECC checking unit 57 in synchronization with the clock signal CLK. The second ECC holding unit 582 receives the ECC (ECCI) from the second selection unit 586, holds the ECC (ECCI), and outputs the ECC (ECCI) as ECC (ECCID) to the ECC checking unit 57 in synchronization with the clock signal CLK.

The ECC checking unit 57 receives the data (DIND) from the second data holding unit 581 and the ECC (ECCID) from the second ECC holding unit 582, and generates ECC for the data (DIND). The ECC for the data (DIND) corresponds to third ECC. Then, the ECC checking unit 57 compares the ECC (ECCID) with the ECC for the data (DIND). If a result of the comparison indicates non-matching between the ECC (ECCID) and the ECC for the data (DIND), the ECC checking unit 57 outputs error information indicating non-matching between the ECC (ECCID) and the ECC for the data (DIND), and the data (DIND) to the interruption controller 7. The ECC checking unit 57 outputs the data (DIND) as read data (DINDD) to the read buffer 56 according to a reading control signal supplied during the reading. The read buffer 56 outputs the read data (DINDD) to a reading destination.

Next, a case where delays caused by wiring lines are taken into consideration is described. Operations similar to those described above are omitted.

The first selection unit 585 selects an output of the first delay unit 583 among outputs of the second data output unit 601-2 and the first delay unit 583 according to a delay valid signal. The second selection unit 586 selects an output of the second delay unit 584 among outputs of the second ECC output unit 602-2 and the second delay unit 584 according to the delay valid signal. It is presumed that time of transmission of write data (DOUT) from the first data holding unit 531 to the memory 8 and time of transmission of ECC (ECCO) from the first ECC holding unit 532 to the memory 8 are equal to each other. It is presumed that time of transmission of the write data (DOUT) as data (DIN) from the first data holding unit 531 to the second data holding unit 581 and time of transmission of the ECC (ECC) as ECC (ECCI) from the first ECC holding unit 532 to the second ECC holding unit 582 are equal to each other.

When first delay time and second delay time are different (in this case, the first delay time is longer than the second delay time), the first and second delay units 583 and 584 adjust the second delay time so as to match the second delay time with the first delay time. The first delay time represents time of transmission of the write data (DOUT) and the ECC (ECCO) respectively from the first data holding unit 531 and the first ECC holding unit 532 to the memory 8. The second delay time represents time of transmission of the write data (DOUT) and the ECC (ECCO) respectively from the first data holding unit 531 and the first ECC holding unit 532 to the second data holding unit 581 and the second ECC holding unit 582.

When the first delay time is longer than the second delay time, a delay adjust signal is supplied to the first and second delay units 583 and 584. The delay adjust signal represents a command to adjust difference time that is a difference between the first delay time and the second delay time. The first delay unit 583 holds data (DIN) from the second data output unit 601-2. The first delay unit 583 delays the data (DIN) by the difference time according to the delay adjust signal and outputs the delayed data to the second data holding unit 581 via the first selection unit 585. The second delay unit 584 holds ECC (ECCI) from the second ECC output unit 602-2. The second delay unit 584 delays the ECC (ECCI) by the difference time according to the delay adjust signal and outputs the delayed ECC to the second ECC holding unit 582 via the second selection unit 586.

According to the memory system of the first embodiment of the present invention, during writing, if write data is looped back, and the write data is an error, the error has occurred between the first and second processing units 51 to 53 and 56 to 58 and the input/output unit 60. Thus, as a first effect, whether an error has occurred between the first and second processing units 51 to 53 and 56 to 58 and the input/output unit 60 or in the memory 8 can be specified.

When the data terminal is used for two ways as in the case of a single data rate synchronous dynamic random access memory (SDR SDRAM), normally, during writing, a path (second processing units 56 to 58) of the read side is not operated. On the other hand, according to the memory system of the first embodiment of the present invention, during writing, the write data is looped back to use a path of the read side. As a result, whether or not the write data is an error can be checked.

According to the memory system of the first embodiment of the present invention, during reading, if read data is an error, the error has occurred among the first and second processing units 51 to 53 and 56 to 58, the input/output unit 60 and the memory 8. For example, if write data is not an error, the error may have occurred in the memory 8. Thus, as a second effect, whether an error has occurred between the first and second processing units 51 to 53 and 56 to 58 and the input/output unit 60 or in the memory 8 can be specified.

According to the memory system of the first embodiment of the present invention, a skew between the first data holding unit 531 and the memory 8 and a skew between the first and second data holding units 531 and 581 are adjusted. A skew between the first ECC holding unit 532 and the memory 8 and a skew between the first ECC holding unit 532 and the second ECC holding unit 582 are adjusted. Thus, as a third effect, the error can be specified by taking delays caused by wiring lines into consideration.

### Second Embodiment

A second embodiment is directed to a memory 8 that uses a strobe signal as in the case of a double data rate synchronous dynamic random access memory (DDR SDRAM). In this case, a delay locked loop (DLL) described below is added to a memory controller 5. Description of components of the second embodiment similar to those of the first embodiment is omitted.

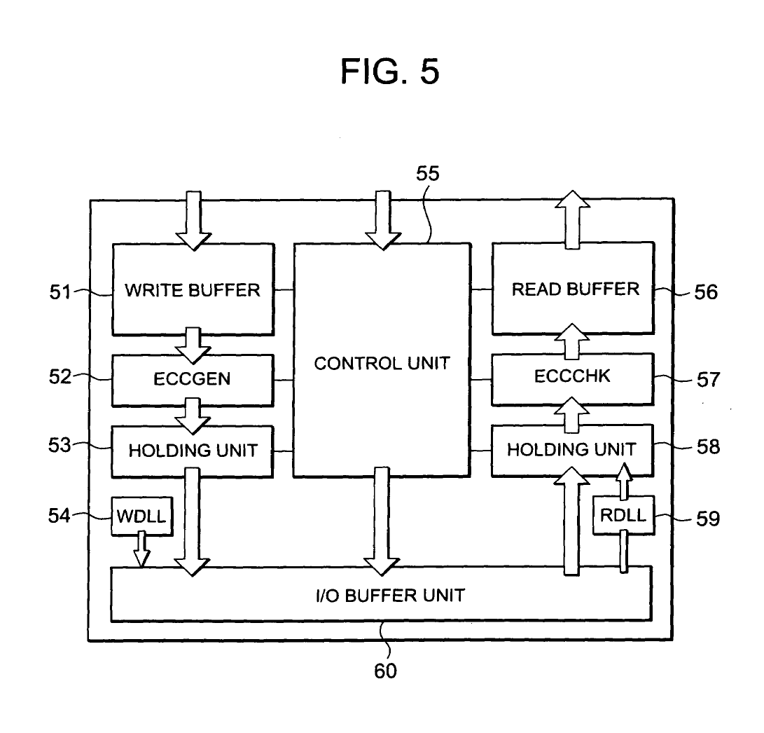

FIG. 5 illustrates a configuration of the memory controller of a memory system according to the second embodiment of the present invention. The memory controller 5 includes a first DLL (WDLL) unit 54 and a second DLL (RDLL) unit 59 in place of the first and second delay units 583 and 584 and the first and second selection units 585 and 586 in the second holding unit 58. In other words, the first and second DLL units 54 and 59 are added to the memory controller 5 to eliminate the necessity of the first and second delay units 583 and 584 and the first and second selection units 585 and 586 in the second holding unit 58.

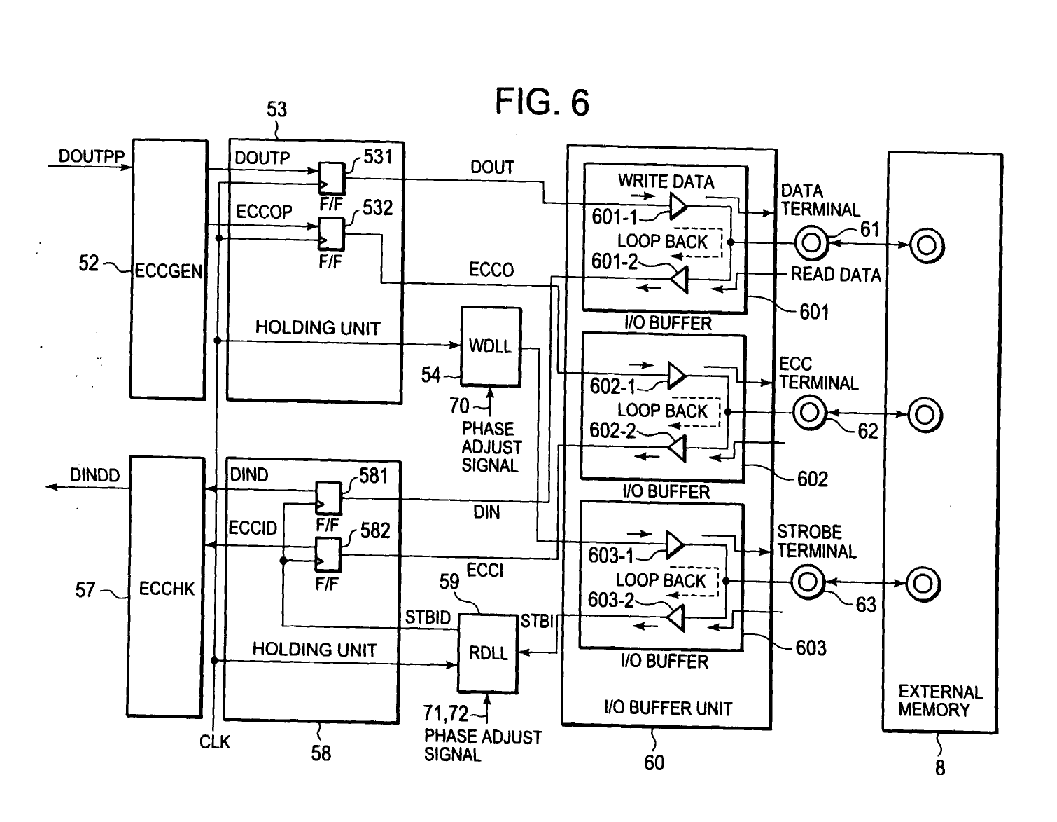

FIG. 6 illustrates an ECC generation unit 52, a first holding unit 53, the first DLL unit 54, an ECC checking unit 57, a second holding unit 58, the second DLL unit 59, and an input/output unit 60 in the memory controller 5.

The memory controller 5 further includes a strobe terminal 63. The memory 8 includes a strobe terminal connected to the strobe terminal 63. For example, it is presumed that 64 data terminals 61, 8 ECC terminals 62, and 8 strobe terminals 63 are installed, and components of the memory controller 5 are configured according the numbers of the terminals 61 to 63.

The input/output unit 60 further includes a strobe output unit 603. The strobe output unit 603 includes first and second strobe output units 603-1 and 603-2 (output buffers). The first strobe output unit 603-1 is disposed between an output of the first DLL unit 54 and the strobe terminal 63. The second strobe output unit 603-2 is disposed between an output of the first strobe output unit 603-1 and the second DLL unit 59.

A clock signal CLK is supplied as a first clock signal to the first and second DLL units 54 and 59. The first and second clock signals are different from each other. During writing, a phase adjust signal 70 is supplied to the first DLL unit 54, and a first phase adjust signal 71 is supplied to the second DLL unit 59. During reading, a second phase adjust signal 72 is supplied to the second DLL unit 59. Those phase adjust signals are described below.

The configuration of the memory system of the second embodiment of the present invention provides a third effect in addition to the first and second effects.

An operation of the memory controller 5 of the second embodiment of the present invention is described. The same description as that of the above is omitted.

First, a process during writing is described.

During writing, the first DLL unit 54 outputs a write strobe signal obtained by shifting a phase of a clock signal CLK to the first strobe output unit 603-1.

The first strobe output unit 603-1 outputs the write strobe signal from the first DLL unit 54 to the memory 8 via the strobe terminal 63. The second strobe output unit 603-2 outputs the write strobe signal from the first strobe output unit 603-1 as an adjust strobe signal (STBI) to the second DLL unit 59.

When first delay time and second delay time are different from each other, the second DLL unit 59 adjusts the second delay time so as to match the second delay time with the first delay time. The first delay time represents a difference between time of transmission of write data and first ECC from the first data holding unit 531 and the first ECC holding unit 532 to the memory 8 and time of transmission of the write strobe signal from the first DLL unit 54 to the memory 8. The second delay time represents a difference between transmission time of the write data and the first ECC respectively as output data and second ECC from the first data holding unit 531 and the first ECC holding unit 532 to the second data holding unit 581 and the second ECC holding unit 582 and time of transmission of the write strobe signal from the first DLL unit 54 to the second DLL unit 59.

When the first delay time and the second delay time are different from each other, a first phase adjust signal 71 is supplied to the second DLL unit 59. The first phase adjust signal 71 represents a command to adjust difference time that is a difference between the first delay time and the second delay time. The second DLL unit 59 holds the adjust strobe signal (STBI) from the second strobe output unit 603-2. The second DLL unit 59 delays the adjust strobe signal (STBI) by the difference time according to the first phase adjust signal 71 and the clock signal CLK and outputs the delayed adjust strobe signal (STBI) as an adjust strobe signal (STBID) to the second data holding unit 581 and the second ECC holding unit 582. The adjust strobe signal (STBID) corresponds to a second clock signal.

In this case, a phase adjust signal 70 is supplied to the first DLL unit 54. During writing, the first DLL unit 54 outputs a write strobe signal to the first strobe output unit 603-1 according to the phase adjust signal 70 and the clock signal CLK.

Next, a process during reading is described. The same description as that of the above is omitted.

During reading, a read strobe signal is output from the memory 8. In this case, the second strobe output unit 603-2 outputs the read strobe signal from the memory 8 as an adjust strobe signal (STBI) to the second DLL unit 59.

The second DLL unit 59 has to adjust a phase of the adjust strobe signal to a desired phase during the reading.

In this case, a second phase adjust signal 72 is supplied to the second DLL unit 59. The second phase adjust signal 72 represents a command to adjust a phase of the adjust strobe signal to a desired phase. The second DLL unit 59 holds the adjust strobe signal (STBI) from the second strobe output unit 603-2. The second DLL unit 59 adjusts a phase of the adjust strobe signal (STBI) according to the second phase adjust signal 72 and the clock signal CLK and outputs the adjust strobe signal (STBI) with the adjusted phase as an adjust strobe signal (STBID) to the second data holding unit 581 and the second ECC holding unit 582. The adjust strobe signal (STBID) corresponds to a second clock signal.

The memory 8 uses a strobe signal as in the case of DDR SDRAM. In this case, during the reading, a strobe signal (read strobe signal) is used as a clock signal to the second data holding unit 581 and the second ECC holding unit 582 (F/F). The second data holding unit 581 and the second ECC holding unit 582 latch output data (read data) according to the strobe signal. In this case, before the strobe signal is supplied to the second data holding unit 581 and the second ECC holding unit 582, a phase of the strobe signal has to be shifted by about 90°. The DLL is used for this purpose. The DLL can generally fine-adjust a phase.

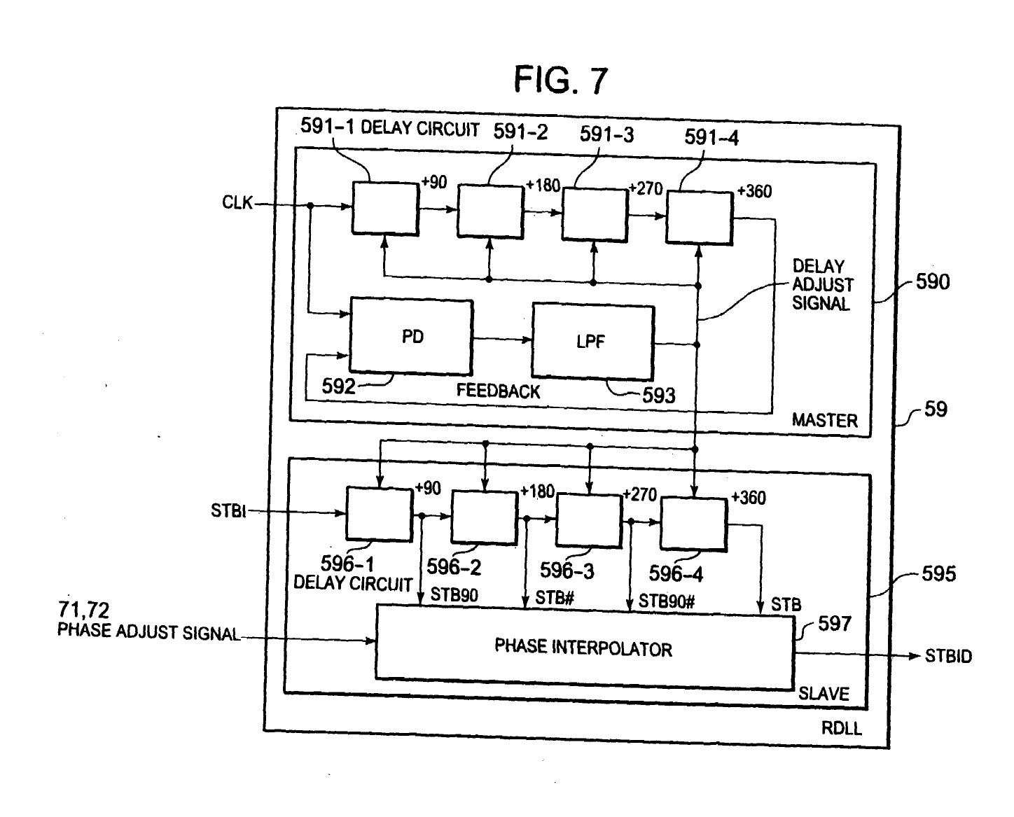

FIG. 7 illustrates a configuration of the second DLL unit 59.

The second DLL unit 59 includes a master unit (MASTER) 590 and a slave unit (SLAVE) 595.

The master unit 590 includes delay circuits 591-1 to 591-4, a phase detector (PD) 592, and a low-pass filter (LPF) 593. The delay circuits 591-1 to 591-4 are serially connected in this order. The delay circuit 591-4 is connected to the phase comparator 592. The phase detector 592 is connected to the low-pass filter 593. The low-pass filter is connected to the delay circuits 591-1 to 591-4 and the slave unit 595. A clock signal CLK is supplied to the delay circuit 591-1 and the phase detector 592. The delay circuits 591-1 to 591-4 delay the clock signal CLK by 90° based on a delay adjust signal. The delay circuit 591-4 outputs the clock signal CLK as a clock signal (FEEDBACK) to the phase detector 592. The phase detector 592 compares the clock signal CLK with the clock signal (FEEDBACK) for phase, and adjusts the number of stages of the delay circuits 591-1 to 591-4 to obtain the number of stages similar in phase to the clock signal CLK. The phase detector 592 outputs the number of stages as a delay adjust signal to the delay circuits 591-1 to 591-4 and the slave unit 595 via the low-pass filter 593.

The slave unit 595 includes delay circuits 596-1 to 596-4 and a phase interpolator 597. The delay circuits 596-1 to 596-4 are serially connected in this order. The delay circuits 596-1 to 506-4 are connected to the low-pass filter 593 of the master unit 590. The phase interpolator 597 is connected to the delay circuits 596-1 to 596-4. An adjust strobe signal (STBI) received from the second strobe output unit 603-2 is supplied to the delay circuit 596-1. A delay adjust signal received from the master unit 590 is supplied to the delay circuit 596-1. A second phase adjust signal 72 is supplied as a phase adjust signal to the phase interpolator 597. The delay circuits 596-1 to 596-4 delay the adjust strobe signal (STBI) by 90° respectively based on the delay adjust signal. As a result, for the adjust strobe signal (STBI), the delay circuits 596-1 to 596-4 generate a four-layer clock of a 90°-delayed strobe signal (STB90), a 180°-delayed strobe signal (STB#), a 270°-delayed strobe signal (STB90#), and a 360°-delayed strobe signal (STB). The four-layer clock is supplied to the phase interpolator 597. The phase interpolator 597 that can adjust a phase within a range of 0 to 360° based on a phase adjust signal outputs the adjust strobe signal (STBI) to the second data holding unit 581 and the second ECC holding unit 582 by using a phase-adjusted strobe signal as an adjust strobe signal (STBID).

According to the second embodiment, during ECC checking of the write data, changing a phase adjust signal from the second phase adjust signal 72 to the first phase adjust signal 71 by using the second DLL unit 59 enables fine skew adjustment for the adjust strobe signal (STBID) and the data (DIN)/ECC (ECCI).

According to the memory system of the second embodiment of the present invention, in addition to the first to third effects, the use of the RDDL (second DLL unit 59) during reading enables elimination of a necessity of adding delay circuits or selectors (first and second delay units 583 and 584 and first and second selection units 585 and 586). The use of the DLL enables phase adjustment with great accuracy, and the error can be specified by taking skew causes such as wiring lines with the memory 8 into consideration to a certain extent.

It is apparent that the present invention is not limited to the above embodiments, but may be modified and changed without departing from the scope and spirit of the invention.

What is claimed is:

1. A memory system, comprising:
a first processing unit receiving, during writing, write data to generate a first error correcting code (ECC) for the write data, and outputting the write data and the first ECC;
an input/output unit outputting the write data and the first ECC outputted from the first processing unit to a memory, and outputting the write data as output data and the first ECC as a second ECC; and
a second processing unit receiving the output data and the second ECC to generate a third ECC for the output data, comparing the third ECC with the second ECC, and outputting a result of the comparison and the output data.

2. The memory system according to claim 1, wherein when read data and an ECC for the read data are read from the memory during reading, the input/output unit outputs the read data and the ECC for the read data read from the memory respectively as the output data and the second ECC to the second processing unit.

3. The memory system according to claim 2, wherein the second processing unit is configured to:
output, when the result of the comparison indicates that the second ECC and the third ECC do not match each other, error information indicating that the second ECC and the third ECC do not match each other; and
output the output data according to a read control signal supplied during the reading.

4. The memory system according to claim 1, wherein the input/output unit comprises:
a first data output unit that outputs the write data output from the first processing unit to the memory;
a second data output unit that outputs the write data output from the first data output unit as the output data to the second processing unit;
a first ECC output unit that outputs the first ECC output from the first processing unit to the memory; and
a second ECC output unit that outputs the first ECC output from the first ECC output unit as the second ECC to the second processing unit.

5. The memory system according to claim 4, wherein:
the first processing unit comprises:
an ECC generation unit that receives, during the writing, the write data to generate the first ECC for the write data;
a first data holding unit that receives and holds the write data, and outputs the write data to the first data output unit in synchronization with a first clock signal; and
a first ECC holding unit that holds the first ECC output from the ECC generation unit, and outputs the first ECC to the first ECC output unit in synchronization with the first clock signal; and
the second processing unit comprises:
a second data holding unit that holds the output data output from the second data output unit, and outputs the output data in synchronization with a second clock signal;
a second ECC holding unit that holds the second ECC output from the second ECC output unit, and outputs the second ECC in synchronization with the second clock signal; and
an ECC checking unit that generates the third ECC for the output data output from the second data holding unit, compares the third ECC with the second ECC output from the second ECC holding unit, and outputs the result of the comparison and the output data.

6. The memory system according to claim 5, further comprising an adjusting unit that adjusts a delay so as to match first delay time between the first processing unit and the memory with second delay time between the first processing unit and the second processing unit.

7. The memory system according to claim 6, wherein:
the first delay time represents time of transmission of the write data and the first ECC respectively from the first data holding unit and the first ECC holding unit to the memory;
the second delay time represents time of transmission of the write data and the first ECC respectively from the first data holding unit and the first ECC holding unit to the second data holding unit and the second ECC holding unit; and
when the first delay time and the second delay time are different from each other, the adjusting unit adjusts the second delay time so as to match the first delay time with the second delay time.

8. The memory system according to claim 7, wherein:
the first clock signal and the second clock signal are identical;
the adjusting unit comprises a first delay unit and a second delay unit to which, when the first delay time and the second delay time are different from each other, a delay adjust signal for adjusting difference time representing a difference between the first delay time and the second delay time is supplied;
the first delay unit holds the output data output from the second data output unit, and delays the output data by the difference time according to the delay adjust signal to output the output data to the second data holding unit; and
the second delay unit holds the second ECC output from the second ECC output unit, and delays the second ECC by the difference time according to the delay adjust signal to output the second ECC to the second ECC holding unit.

9. The memory system according to claim 8, wherein the adjusting unit further comprises:
a first selection unit that outputs the output data output from the second data output unit to the second data holding unit according to a delay invalid signal, and outputs the output data output from the first delay unit to the second data holding unit according to a delay valid signal; and
a second selection unit that outputs the second ECC output from the second ECC output unit to the second ECC holding unit according to the delay invalid signal, and outputs the second ECC output from the second delay unit to the second ECC holding unit according to the delay valid signal.

10. The memory system according to claim 6, wherein:
the adjusting unit comprises:
a first delay locked loop (DLL) unit that outputs a write strobe signal during the writing; and
a second DLL unit;
the input/output unit further comprises:
a first strobe output unit that outputs the write strobe signal output from the first DLL unit to the memory; and
a second strobe output unit that outputs the write strobe signal output from the first strobe output unit as an adjust strobe signal to the second DLL unit;
the first delay time represents a difference between time of transmission of the write data and the first ECC respectively from the first data holding unit and the first ECC holding unit to the memory and time of transmission of the write strobe signal from the first DLL unit to the memory;
the second delay time represents a difference between time of transmission of the write data and the first ECC respectively from the first data holding unit and the first ECC holding unit to the second data holding unit and the second ECC holding unit and time of transmission of the write strobe signal from the first DLL unit to the second DLL unit; and
when the first delay time and the second delay time are different from each other, the second DLL unit adjusts the second delay time so as to match the first delay time with the second delay time.

11. The memory system according to claim 10, wherein:
the first clock signal and the second clock signal are different from each other;
when the first delay time and the second delay time are different from each other, the second DLL unit is supplied with a first phase adjust signal for adjusting difference time representing a difference between the first delay time and the second delay time; and
the second DLL unit delays, according to the first phase adjust signal and the first clock signal, the adjust strobe signal output from the second strobe output unit by the difference time to output the adjust strobe signal as the second clock signal to the second data holding unit and the second ECC holding unit.

12. The memory system according to claim 11, wherein, when a read strobe signal is output from the memory during the reading:
the second strobe output unit outputs the read strobe signal output from the memory as the adjust strobe signal to the second DLL unit;
the second DLL unit is supplied with a second phase adjust signal for adjusting a phase of the adjust strobe signal to a desired phase; and
the second DLL unit adjusts, according to the second phase adjust signal and the first clock signal, the phase of the adjust strobe signal output from the second strobe output unit to the desired phase to output the adjust strobe signal as the second clock signal to the second data holding unit and the second ECC holding unit.

13. A memory error cause specifying method, comprising:
receiving, by a first processing unit, during writing, write data to generate a first error correcting code (ECC) for the write data, and outputting the write data and the first ECC;
outputting, by an input/output unit, the write data and the first ECC output from the first processing unit to a memory, and outputting the write data and the first ECC respectively as output data and a second ECC; and
receiving, by a second processing unit, the output data and the second ECC to generate a third ECC for the output data, comparing the third ECC with the second ECC, and outputting a result of the comparison and the output data.

14. The memory error cause specifying method according to claim 13, wherein when read data and an ECC for the read data are read from the memory during reading, the outputting, by the input/output unit, outputs the read data and the ECC for the read data read from the memory respectively as the output data and the second ECC.

15. The memory error cause specifying method according to claim 14, wherein the receiving, by the second processing unit, comprises:
outputting, when the result of the comparison indicates that the second ECC and the third ECC do not match each other, error information indicating that the second ECC and the third ECC do not match each other; and
outputting the output data according to a read control signal supplied during the reading.

16. The memory error cause specifying method according to claim 13, further comprising adjusting, by an adjusting unit, a delay so as to match first delay time between the first processing unit and the memory with second delay time between the first processing unit and the second processing unit.

17. A memory system, comprising:
a memory;
a memory interface unit that is connected to the memory, and is used for inputting and outputting write data, read data and error correcting codes (ECCs) corresponding to the write data and the read data to and from the memory;
a write data processing unit that is connected to the memory interface unit, and outputs the write data to be output to the memory and a first ECC generated from the write data to the memory interface unit;
a read data processing unit that is connected to the memory interface unit, and receives the read data output from the memory and a second ECC corresponding to the read data; and
an ECC checking unit that is connected to the read data processing unit, generates a third ECC from the read data, and compares the third ECC with the second ECC,
wherein when outputting the write data to the memory, the memory interface unit outputs the write data and the first ECC respectively as the read data and the second ECC to the read data processing unit.

18. The memory system according to claim 17, further comprising a delay adjusting unit that adjusts a delay so as to match first delay time between the write data processing unit and the memory with second delay time between the write data processing unit and the read data processing unit.
